(19) United States
(12) Patent Application Publication
(10) Pub. No.: US 2024/0069111 A1
(43) Pub. Date: Feb. 29, 2024

(54) NETWORK RESTART FROM POWER SAVE MODE IN WBMS

(71) Applicant: TEXAS INSTRUMENTS INCORPORATED, Dallas, TX (US)

(72) Inventors: Ariton E. XHAFA, Plano, TX (US); Tariq Ihab MUHANNA, Garland, TX (US); Mathew GIARAMITA, New York, NY (US); Naveen Kumar KALA, Austin, TX (US)

(21) Appl. No.: 17/900,670

(22) Filed: Aug. 31, 2022

(51) Int. Cl. G01R 31/371; G01R 31/382; H01M 10/42

(52) U.S. Cl. CPC G01R 31/371; G01R 31/382; H01M 10/425; H01M 2010/4271; H01M 2220/20

(57) ABSTRACT

In an example, a wireless battery management system includes one or more sets of battery cells. The wireless battery management system includes a primary node configured to broadcast a downlink packet in a first superframe. The wireless battery management system also includes a first secondary node coupled to a first set of battery cells. The first secondary node is configured to receive the downlink packet and transmit a first uplink packet to the primary node during the first superframe. The wireless battery management system includes a second secondary node coupled to a second set of battery cells. The second secondary node is configured to receive the first uplink packet from the first secondary node in the first superframe. The second secondary node is also configured to transmit a second uplink packet to the primary node during a second superframe.

### BACKGROUND

Modern vehicles may include multiple battery cells. Sensors may monitor information associated with the cells, such as temperature, voltage, and other indicators of cell status and health, for vehicular safety and to ensure proper operation.

### SUMMARY

In accordance with at least one example of the description, a wireless battery management system includes one or more sets of battery cells. The wireless battery management system includes a primary node configured to broadcast a downlink packet in a first superframe. The wireless battery management system also includes a first secondary node coupled to a first set of battery cells. The first secondary node is configured to receive the downlink packet and transmit a first uplink packet to the primary node during the first superframe. The wireless battery management system includes a second secondary node coupled to a second set of battery cells. The second secondary node is configured to receive the first uplink packet from the first secondary node in the first superframe. The second secondary node is also configured to transmit a second uplink packet to the primary node during a second superframe.

In accordance with at least one example of the description, a method includes transmitting a downlink packet from a primary node to one or more secondary nodes in a first superframe in a wireless battery management system. The method includes receiving the downlink packet at a first secondary node. The method also includes transmitting a first uplink packet from the first secondary node to the primary node in the first superframe. The method also includes receiving the first uplink packet at a second secondary node in the first superframe. The method includes transmitting a second uplink packet from the second secondary node to the primary node during a second superframe.

In accordance with at least one example of the description, a method includes transmitting a first downlink packet from a primary node to one or more secondary nodes in a first superframe. The method also includes receiving the first downlink packet at a first secondary node in the first superframe. The method includes failing to receive the first downlink packet at a second secondary node in the first superframe. The method also includes transmitting a first uplink packet from the first secondary node to the primary node in the first superframe. The method includes transmitting a second downlink packet from the primary node to the one or more secondary nodes in a second superframe. The method includes receiving the second downlink packet at the second secondary node in the second superframe. The method also includes transmitting a second uplink packet from the second secondary node to the primary node in the second superframe.

### BRIEF DESCRIPTION OF THE DRAWINGS

FIG. 1 is a block diagram of a wireless battery management system according to various examples.

FIG. 2 is a block diagram of a wireless battery management system according to various examples.

FIG. 3A is a superframe interval usable by a wireless battery management system according to various examples.

FIG. 3B is a superframe interval usable by a wireless battery management system according to various examples.

FIGS. 4A and 4B show consecutive superframe intervals usable by a wireless battery management system according to various examples.

FIG. 5A is a graph of scaled power consumption for a secondary network node according to various examples.

FIG. 5B is a graph of scaled power consumption for a primary node in accordance with various examples.

FIG. 6 is a table of approximate power consumption at the primary node and at secondary nodes in accordance with various examples.

FIG. 7 is a flow diagram of a method for a network restart from a power save mode in accordance with various examples.

FIG. 8 is a flow diagram of a method for a network restart from a power save mode in accordance with various examples herein.

The same reference numbers or other reference designators are used in the drawings to designate the same or similar (functionally and/or structurally) features.

### DETAILED DESCRIPTION

Some electronic devices operate using batteries. For example, electric vehicles include multiple battery cells that provide power to those vehicles. Because battery cells in an electronic device can provide large amounts of power, and further because the power provided by the battery cells may be vital to the operation of the electronic device, the electronic device may include a system to manage the battery cells.

Battery management systems (BMSs) may manage the battery cells of an electronic device in various ways. For example, a BMS may monitor the health (e.g., voltage, current, temperature) of battery cells in an electronic device. Further, the BMS may control various battery cells to manage the quantity of power provided by the battery cells and direct that power within the electronic device. Generally, a BMS includes multiple components, such as multiple battery modules and a controller to manage the battery modules. Each battery module, in turn, may couple to multiple battery cells and include a battery monitor to monitor those battery cells. Thus, the battery cells coupled to a battery module provide power to the electronic device; the battery monitor in the battery module monitors the health and operation of the battery cells in that battery module; and the controller communicates with the battery monitor to ensure the battery module and its cells operate properly. The controller may also communicate with the battery monitor to control the operation of the battery cells, such as to turn on, turn off, redirect, or otherwise balance the power provided by those battery cells.

BMSs may incorporate wireless technology to create a wireless battery management system (WBMS). For example, a primary network node contains or is coupled to a controller and a secondary network node contains a battery module that controls multiple battery cells. The primary and secondary network nodes may communicate with each other wirelessly, for example using radio frequencies. In some protocols, a superframe is useful to facilitate wireless communications between the primary and secondary network nodes. In the superframe, the primary network node first broadcasts a downlink (DL) communication (or packet) to multiple secondary network nodes. The secondary network nodes individually respond to the primary network node with uplink (UL) communications (or packets) in a serial manner. Superframes are further described below.

A WBMS may have certain requirements for reliable operation, such as a certain throughput level, data speed, packet error rate, power consumption at each device (including the primary node), and a guarantee in how quickly sensors or monitors send data collected from the battery cells. Some example requirements may include a bandwidth of 600 kilobits per second (kbps), a data latency of less than 100 milliseconds (ms), a packet error rate better than 10⁻⁵, and power consumption of less than 1 milliamp (mA) at the primary node and less than 300 microamps (μA) at the secondary nodes.

Power consumption may be considered during two states: when the vehicle is on, and when the vehicle is off. If the vehicle is on, the vehicle battery or other high voltage batteries may power the wireless nodes. If the vehicle is off, the wireless nodes enter a shutdown mode that consumes less power. However, in one example, after the vehicle turns back on, the wireless nodes should start up and have the WBMS network operating in less than 300 ms, and preferably as fast as possible.

The wireless nodes in a WBMS network may communicate with one another using a time interval knows as a superframe. A superframe is divided into slots, which may be further assigned as downlink slots and uplink slots. Downlink slots transmit a packet from the primary node to a secondary node. Uplink slots transmit a packet from a secondary node to the primary node. In some examples, the primary node transmits a broadcast packet in a downlink slot, and the broadcast packet is received by all the secondary nodes.

If the vehicle is off and the WBMS is not active, a keep alive approach may be useful in some examples. During some superframe intervals, no activity will occur. Then, an active keep alive superframe occurs, which may have a downlink and multiple uplinks. Following the active keep alive superframe, one or more quiet superframes occur. After the quiet superframes, another active keep alive superframe occurs, and the process repeats as needed. This approach preserves power when the vehicle is off.

If the vehicle is off and then turns on, an interrupt is sent to the primary node. The interrupt could arrive in an idle superframe or in an active superframe. If the primary node is active and can incorporate the interrupt information in a downlink packet, it does so and sends that information to each secondary node (e.g., a wake up signal). The secondary nodes can then respond. However, if the interrupt occurs during an idle superframe, the secondary nodes may not be active and listening. Instead, the secondary nodes may be idle and waiting for the next active keep alive superframe. In that scenario, the primary node waits for the next active superframe to transmit the wake up signal. However, a secondary node may not receive the downlink packet during the next active superframe for a variety of reasons, such as interference with the wireless signal. In that instance, the WBMS would have to wait for yet another active superframe for all secondary nodes to wake up and respond. This scenario increases the time for the network to restart.

In examples herein, a first secondary node that fails to receive an expected downlink packet from the primary node during an active superframe may be configured to turn on its receiver to opportunistically listen to other frames being transmitted from other secondary nodes to the primary node during the active superframe. If the first secondary node receives a transmission from another secondary node, the first secondary node wakes up and enters an active state. In other examples herein, the first secondary node that misses the downlink packet from the primary node may be configured to listen with its receiver during the next superframe, rather than listening during the current superframe. If there is any activity in the next superframe, then the WBMS is active, and the first secondary node can continue normal operation.

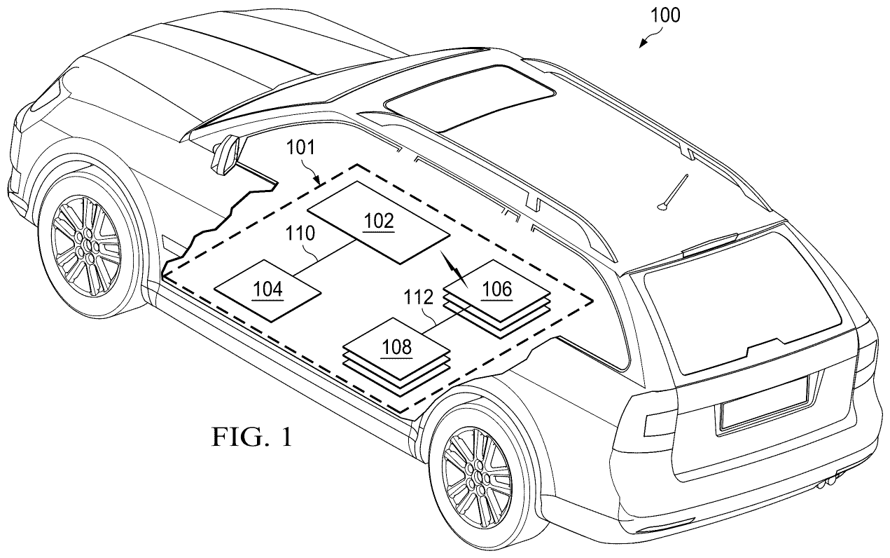

FIG. 1 is a perspective view of an example system 100, such as an automotive vehicle, that includes a WBMS 101. In some examples, the system 100 is any system that may include a wireless battery management system to supply power to one or more components of the system 100. As shown, the WBMS 101 includes a primary network node 102 (also referred to herein as a main node), a battery controller 104, a plurality of secondary network nodes 106, and a plurality of battery cells 108. In an example, the WBMS 101 may include a plurality of primary network nodes. Although this disclosure describes communication techniques primarily in the context of wireless systems, these techniques may also be useful for wired systems (e.g., where the connection between nodes 102 and 106 is wired). Primary network nodes may also be referred to herein as primary nodes, and secondary network nodes may also be referred to herein as secondary nodes.

In an example, the primary network node 102 is coupled to the battery controller 104 using a first wired connection 110. In an example, the first wired connection 110 between the primary network node 102 and the battery controller 104 is a universal asynchronous receiver/transmitter (UART), inter-integrated circuit (I2C), or the like. The secondary network nodes 106 wirelessly couple to the primary network node 102 and couple to the battery cells 108 using a second wired connection 112.

In an example, the WBMS 101 provides wireless radio frequency (RF) communication between the primary network node 102 and the secondary network nodes 106. In an example, the wireless RF communication uses the license-free 2.4 gigahertz (GHz) industrial, scientific, and medical (ISM) band from 2.4 GHz to 2.483 GHz, which is compliant with BLUETOOTH special interest group (SIG). In examples, the WBMS 101 uses 2 megabits per second (Mbps) BLUETOOTH low energy (BLE) across the physical layer (PHY). The Open Systems Interconnection (OSI) model includes the PHY as a layer used for communicating raw bits over a physical medium. In this case, the PHY is free space, which the WBMS 101 uses to wirelessly communicate between the primary network node 102 and the secondary network nodes 106. In an example, the transmission power of the WBMS 101 is less than or equal to 10 decibel-milliwatts (dBm). Additional example details of establishing a communication channel in a WBMS can be found in commonly assigned U.S. patent application Ser. No. 17/233,106, entitled “Wireless Protocol for Battery Management,” filed on Apr. 16, 2021; and U.S. patent application Ser. No. 17/399,793, entitled “Wireless Battery Management System Setup,” filed on Aug. 11, 2021, each of which is incorporated by reference in its entirety.

In an example, the wireless RF communication between the primary network node 102 and the secondary network nodes 106 utilizes frequency hopping and time slotted allocations to transmit and receive data across superframes (SFs). A superframe, also referred to as a superframe interval, is a time interval including time and frequency allocations for data exchanges between the primary network node 102 and the secondary network nodes 106, including interframe spacing between these allocations. Frequency hopping includes transmitting RF signals by rapidly changing the transmission frequency among many distinct frequencies occupying a spectral band. Time slotted allocations are time slots that are assigned either to the primary network node 102 or one or more of the secondary network nodes 106 for transmitting to either one or more of the secondary network nodes 106 or the primary network node 102. The time slotted allocations occur in a half-duplex mode, as both the primary network node 102 and the secondary network nodes 106 switch between transmit and receive modes according to the temporal moment specified in scan/pairing frames of exchanged data for downlink/uplink durations. Additional example details of pairing can be found in commonly assigned U.S. patent application Ser. No. 17/576,001, entitled “Operating Modes for Testing Monitor Circuits,” filed on Jan. 14, 2022, which is incorporated by reference in its entirety.

The WBMS 101 manages the battery cells 108 using the primary network node 102, the battery controller 104, and the secondary network nodes 106. The primary network node 102 and the secondary network nodes 106 communicate with each other about the state of the battery cells 108.

As described above, if the vehicle is off, a keep alive process is useful. For a given keep alive interval N, the keep alive process skips N−1 superframes to wake up in the Nth superframe to handle any activity, before going dormant again. Different approaches may be useful for the keep alive process. A first example is a fully active process. In this process, the primary network node turns on its receiver during an uplink portion of the Nth superframe, and the secondary network nodes transmit their responses to the primary network node. A second example is a partially active process. In this process, the primary network node turns off its receiver during an uplink portion of the Nth superframe, and the secondary network nodes are not expected to transmit a response. Partially active superframes consume less power than fully active superframes. A keep alive process may have any combination of idle superframes, partially active superframes, and fully active superframes.

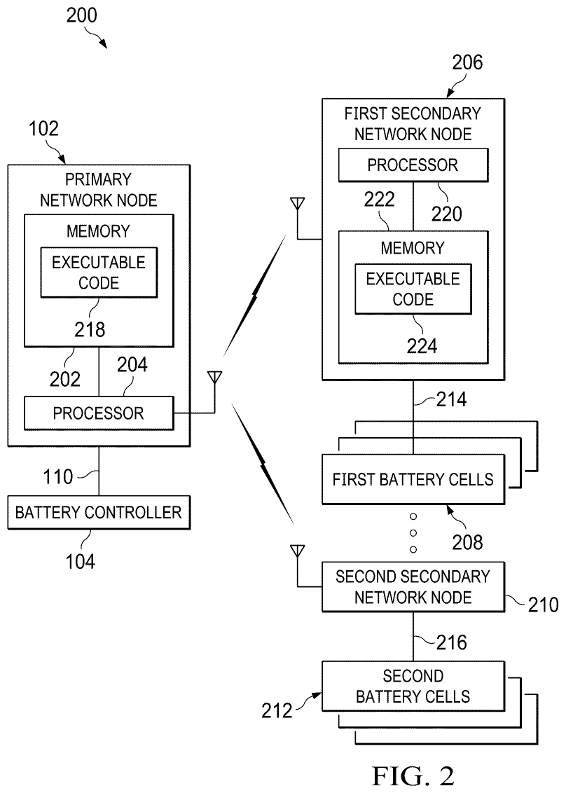

FIG. 2 illustrates an example WBMS 200. The WBMS 200 is an example of the WBMS 101 described above. As shown, the WBMS 200 includes the primary network node 102, the battery controller 104, a memory 202, a processor 204, a first secondary network node 206, a first plurality or set of battery cells 208, a second secondary network node 210, and a second plurality or set of battery cells 212. Additional secondary network nodes 206, 210 may be included, although they are not expressly shown. The primary network node 102 includes the memory 202 and the processor 204 that is configured to execute code 218 stored on the memory 202 to perform one or more of the actions attributed herein to the primary network node 102. In an example, a portion of the memory 202 may be non-transitory and a portion of the memory 202 may be transitory. The secondary network nodes 206, 210 also may include processors and memory. For example, as shown, the first secondary network node 206 includes a processor 220 coupled to a memory 222 storing code 224 that is executable by the processor 220 to perform one or more of the actions attributed herein to the first secondary network node 206.

The primary network node 102 is coupled to the battery controller 104 using the first wired connection 110 and is wirelessly coupled to each of the secondary network nodes 206, 210. The first secondary network node 206 is coupled to the first plurality or set of battery cells 208 using a third wired connection 214 and wirelessly coupled to the primary network node 102. The second secondary network node 210 is coupled to the second plurality or set of battery cells 212 using a fourth wired connection 216 and wirelessly coupled to the primary network node 102. FIG. 2 does not limit the number of secondary network nodes in the WBMS 200; rather, the naming convention indicates that each of the secondary network nodes is coupled to a plurality of battery cells.

In an example, the primary network node 102 is wirelessly coupled to at least eight secondary network nodes 206, 210. In an example, each of the secondary network nodes 206, 210 can be coupled to at least sixteen battery cells using a wired connection. In examples, the WBMS 200 includes one primary network node 102. In other examples, the WBMS 200 includes multiple primary network nodes 102.

The WBMS 200 manages the first plurality of battery cells 208 and the second plurality of battery cells 212 using the primary network node 102, the battery controller 104, the memory 202, the processor 204, the first secondary network node 206, and the second secondary network node 210. Instructions in the memory 202 cause the processor 204 to instruct the primary network node 102 to wirelessly communicate with the first secondary network node 206 and the second secondary network node 210 about the state of the first plurality of battery cells 208 and the second plurality of battery cells 212. The primary network node 102 and the secondary network nodes 206, 210 may communicate using any suitable protocol formats.

Either or both of processors 204 and 220 may include processing circuitry such as one or more processors. Processors 204 and 220 may include any combination of integrated circuitry, discrete logic circuitry, analog circuitry, such as one or more microprocessors, microcontrollers, digital signal processors, application specific integrated circuits, central processing units, graphics processing units, field-programmable gate arrays, and/or any other processing resources. In some examples, processors 204 and 220 may include multiple components, such as any combination of the processing resources listed above, as well as other discrete or integrated logic circuitry, and/or analog circuitry.

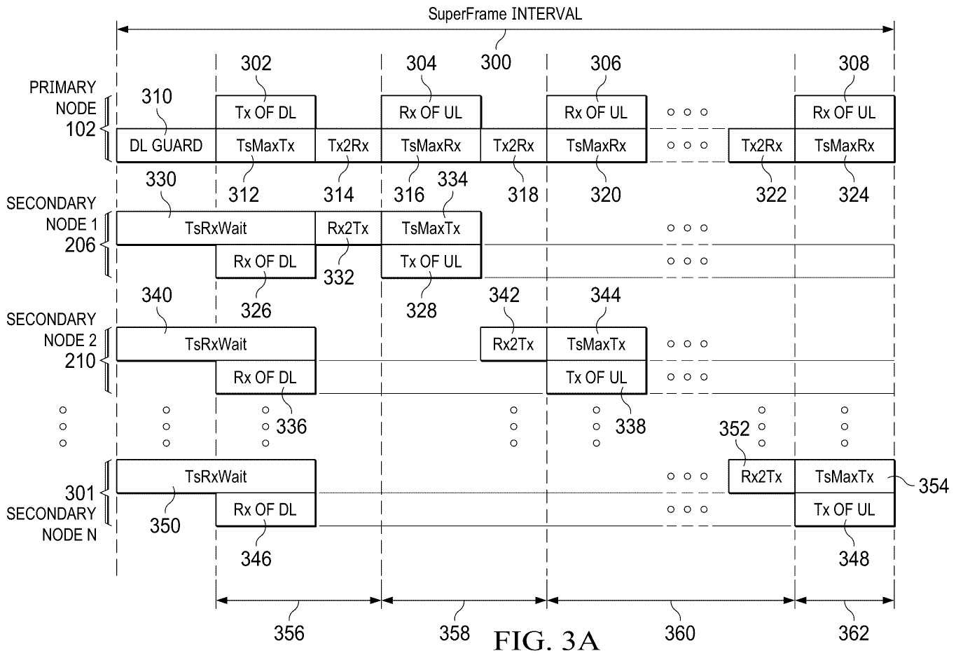

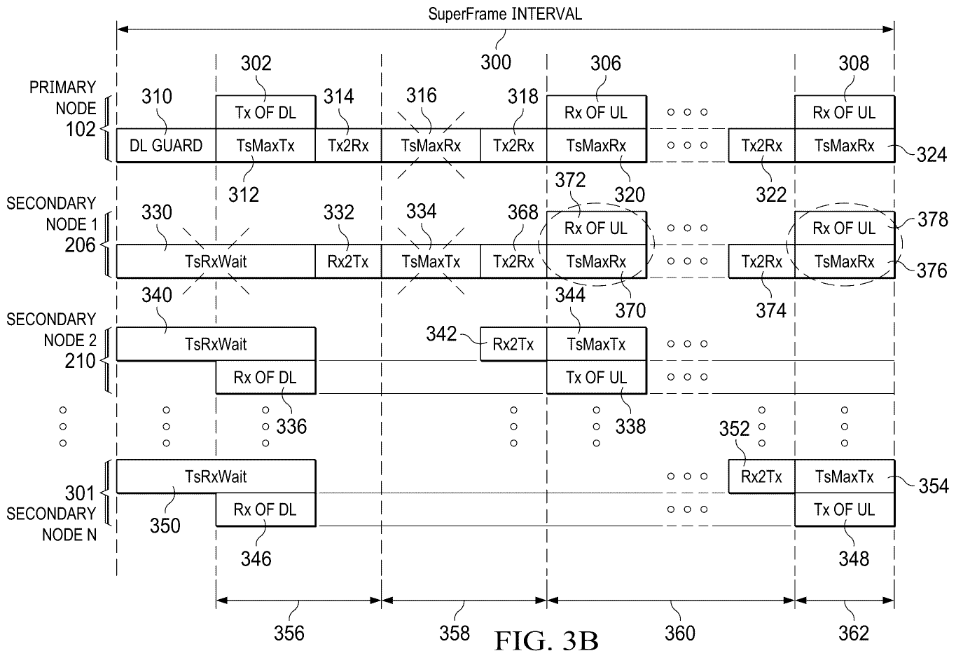

FIG. 3A is an example superframe interval 300 usable by a wireless battery management system, e.g., the WBMS 101. In FIG. 3A, each of the secondary network nodes 106 receive a downlink from primary network node 102 and provide an appropriate response. FIG. 3B, described below, shows a situation where a secondary network node (e.g., 206, 210, etc.) misses a downlink from primary network node 102. Referring again to FIG. 3A, the term TsMaxRx denotes the maximum (Max) time (Ts) allocated for receiving a packet (Rx), and the term TsMaxTx denotes the maximum (Max) time (Ts) allocated for transmitting a packet (Tx). The primary network node 102 communicates with the first secondary network node 206, the second secondary network node 210, and an Nth secondary network node 301 using, for example, the superframe interval 300. As shown, the superframe interval 300 includes a DL transmit frame 302, a first UL receive frame 304, a second UL receive frame 306, a third UL receive frame 308, a DL guard frame 310, a DL transmit time frame 312, a first transmit to receive frame 314, a first UL receive time frame 316, a second transmit to receive frame 318, a second UL receive time frame 320, a third transmit to receive frame 322, a third UL receive time frame 324, a first DL receive frame 326, a first UL transmit frame 328, a first receive wait time 330, a first receive to transmit frame 332, a first UL transmit time frame 334, a second DL receive frame 336, a second UL transmit frame 338, a second receive wait time 340, a second receive to transmit frame 342, a second UL transmit time frame 344, a third DL receive frame 346, a third UL transmit frame 348, a third receive wait time 350, a third receive to transmit frame 352, a third UL transmit time frame 354, a first frame 356, a second frame 358, a third frame 360, and a fourth frame 362. The frames 356, 358, 360, and 362 may be referred to herein as slots 356, 358, 360, and 362, respectively.

The superframe interval 300 organizes communication between the primary network node 102 and the secondary network nodes 106 for wireless battery management purposes. In an example, the superframe interval 300 is a medium access control (MAC) for data exchange between the primary network node 102 and the first secondary network node 206, the second secondary network node 210, and the Nth secondary network node 301. Each of the secondary network nodes 206, 210, 301 in the superframe interval 300 communicates with the primary network node 102 during a time slot as discussed with reference to FIG. 3.

In an example, the superframe interval 300 starts with the DL guard frame 310. The DL guard frame 310 is a time period that ensures no interference between subsequent SFs. At the time of the DL guard frame 310, the first secondary network node 206 enters the first receive wait time 330, the second secondary network node 210 enters the second receive wait time 340, and the Nth secondary network node 301 enters the third receive wait time 350.

In the first frame 356 of the superframe interval 300, after the DL guard frame 310, the primary network node 102 broadcasts the DL using the DL transmit frame 302 during the DL transmit time frame 312 to all of the secondary network nodes 206, 210, 301. The first secondary network node 206 receives the DL using the first DL receive frame 326, the second secondary network node 210 receives the DL using the second DL receive frame 336, and the Nth secondary network node 301 receives the DL using the third DL receive frame 346. After the DL transmit frame 302, the primary network node 102 enters the first transmit to receive frame 314 in preparation to receive the ULs from each of the secondary network nodes 206, 210, 301. At the same time as the primary network node 102 enters the first transmit to receive frame 314, the first secondary network node 206 enters the first receive to transmit frame 332 in preparation to transmit a first UL to the primary network node 102.

In the second frame 358 of the superframe interval 300, the first secondary network node 206 transmits the first UL using the first UL transmit frame 328 and during the first UL transmit time frame 334. The primary network node 102 receives the first UL using the first UL receive frame 304 and during the first UL receive time frame 316. In the second frame 358, the primary network node 102 enters the second transmit to receive frame 318 in preparation to receive a second UL from the second secondary network node 210. The second secondary network node 210 enters the second receive to transmit frame 342 in preparation to transmit a second UL to the primary network node 102.

In the third frame 360 of the superframe interval 300, the second secondary network node 210 transmits the second UL using the second UL transmit frame 338 and during the second UL transmit time frame 344. The primary network node 102 receives the second UL using the second UL receive frame 306 and during the second UL receive time frame 320. In the third frame 360, the primary network node 102 enters the third transmit to receive frame 322 in preparation to receive a third UL from the Nth secondary network node 301. The Nth secondary network node 301 enters the third receive to transmit frame 352 in preparation to transmit a third UL to the primary network node 102.

In the fourth frame 362 of the superframe interval 300, the Nth secondary network node 301 (e.g., the third secondary network node in one example) transmits the third UL using the third UL transmit frame 348 and during the third UL transmit time frame 354. As shown in FIG. 3A, the fourth frame 362 is not necessarily consecutive with the third frame 360. The primary network node 102 receives the third UL using the third UL receive frame 308 and during the third UL receive time frame 324. The schedule of frames 328, 338, and 348 shown in FIG. 3 may be referred to herein as a default uplink packet transmission schedule.

FIG. 3A shows an example process where each secondary node (206, 210, 301, etc.), properly receives the DL from primary network node 102 and responds with a UL. FIG. 3B, described below, shows an example process that a WBMS may follow if at least one of the secondary nodes (206, 210, 301, etc.) misses the DL from primary network node 102 during its respective frame.

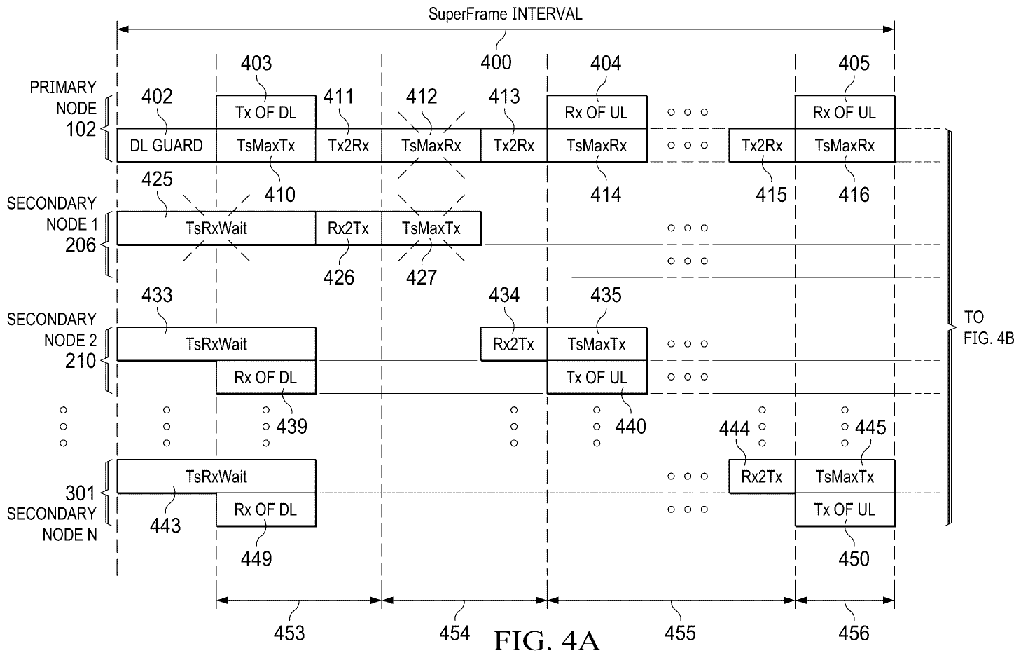

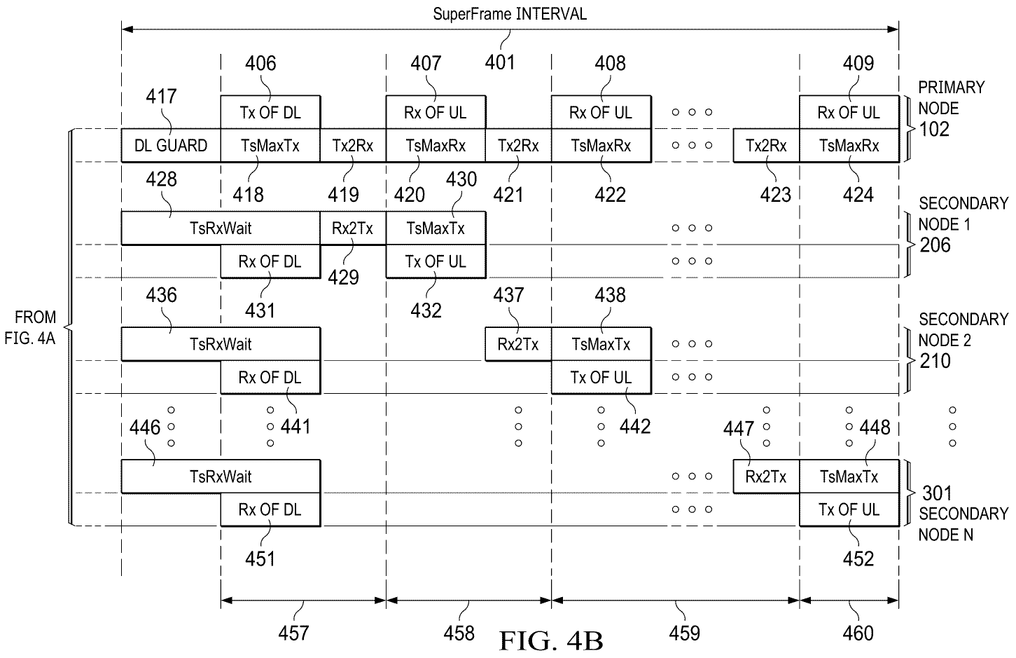

FIG. 3B is another example superframe interval 300 usable by a wireless battery management system, e.g., the WBMS 101. In FIG. 3B, a secondary network node (e.g., 206, 210, 301, etc.) misses a downlink from primary network node 102. FIG. 3B shows one example of the response of an example secondary network node to missing a downlink from primary network node 102. FIGS. 4A and 4B, described below, show another example of a response of an example secondary network node to missing a downlink from primary network node 102.

Many of the components in FIG. 3B are described above with respect to FIG. 3A, and like numerals denote like components. FIG. 3B also includes a fourth transmit to receive frame 368, a fourth UL receive time frame 370, a fourth UL receive frame 372, a fifth transmit to receive frame 374, a fifth UL receive time frame 376, and a fifth UL receive frame 378.

In an example, first secondary network node 206 misses the DL transmit frame 302 from primary network node 102. FIG. 3B shows this missed DL transmit frame with an “X” during first receive wait time 330. In this example, the other secondary nodes, such as second secondary network node 210 and Nth secondary node N, successfully receive the DL transmit frame from primary network node 102. However, in other examples, any number of secondary nodes may miss the DL transmit frame and then, responsive to missing the DL transmit frame, may perform the operations described in this example.

A secondary network node 106 may miss a DL transmit frame from primary network node 102 for a variety of reasons, such as wireless interference (e.g., noise). In an example, the superframe interval 300 is a superframe that occurs one superframe after an idle superframe. That is, the superframe before superframe interval 300 is a superframe where primary network node 102 and the secondary network nodes 106 are idle to preserve power. In superframe interval 300, or in the superframe preceding superframe interval 300, primary network node 102 may receive an interrupt that the vehicle has been turned on. Responsive to the vehicle turning on, WBMS 101 attempts to start up by activating the primary network node 102 and all secondary network nodes 106. As described above, the WBMS 101 may attempt to complete this startup process within 300 ms or less to meet certain performance requirements. To complete the startup process, primary network node 102 checks that all secondary network nodes 106 are active and responsive by sending a DL to each secondary network node 106 and receiving a UL back from each secondary network node 106. If, however, one of the secondary network nodes 106 misses the DL as described herein, in some systems that secondary network node 106 would have to wait for the next superframe interval to receive a DL from a second transmitted DL by primary network node 102. The WBMS 101 cannot start up properly until all secondary network nodes 106 have received the DL from primary network node 102 and responded to primary network node 102. Depending on the length of the superframe interval 300, WBMS 101 may not start up in time to meet certain performance requirements if a secondary network node 106 misses a DL.

In the example described in FIG. 3B, first secondary network node 206 turns on and expects to receive a DL from primary network node 102 during first frame 356. However, first secondary network node 206 misses the DL transmit frame 302 from primary network node 102 during first receive wait time 330. Responsive to expecting a DL but not receiving the DL, first secondary network node 206 turns its receiver on and listens to other frames being transmitted from other secondary network nodes 106. If first secondary network node 206 receives a transmission from another secondary network node 106, first secondary network node 206 recognizes that WBMS 101 is active and completes its wakeup operations to prepare for operation.

In this example, first secondary network node 206 misses the DL transmit frame 302 from primary network node 102 during first receive wait time 330. Therefore, first secondary network node 206 fails to transmit a UL to primary network node 102 during first UL transmit time frame 334 (shown as an “X” in FIG. 3B). Responsive to missing the DL, first secondary network node 206 enters the fourth transmit to receive frame 368 in preparation to receive a UL from another secondary network node 106. Here, at third frame 360, first secondary network node 206 receives a fourth UL receive frame 372 (shown as circled) during fourth UL receive time frame 370. In this example, second secondary network node 210 transmits the fourth UL receive frame, but the UL receive frame could come from any secondary network node 106.

First secondary network node 206 may keep its receiver on and continue to listen for UL frames during superframe interval 300. As shown, first secondary network node 206 enters a fifth transmit to receive frame 374 and receives a fifth UL receive frame 378 (shown as circled) during fifth UL receive time frame 376. First secondary network node 206 may receive any number of UL frames from other secondary network nodes 106. In other examples, first secondary network node 206 may stop listening for UL frames after receiving a UL frame from another secondary network node 106.

If first secondary network node 206 wakes up to listen for transmissions from other secondary network nodes 106, it does not need to wake up for the entire superframe. Rather, first secondary network node 206 may wake just long enough to receive a transmission from another secondary network node 106. If it does not receive a transmission from another secondary network node 106, first secondary network node 206 may go back to a sleep mode or an idle mode. Also, if first secondary network node 206 detects a transmission from another secondary network node 106, it may wait for the next superframe interval to transmit a UL to primary network node 102, so that it can transmit its UL during an appropriate frame.

In this example, first secondary network node 206 misses a DL from primary network node 102 but still turns on during superframe interval 300. This example allows WBMS 101 to wake up and become active quickly enough to meet certain performance requirements, particularly as WBMS 101 exits a power save mode.

FIGS. 4A and 4B show example consecutive superframe intervals 400 and 401 usable by a wireless battery management system, e.g., the WBMS 101. FIG. 4A shows superframe 400, and FIG. 4B shows superframe 401. In FIGS. 4A and 4B, a secondary network node (e.g., 206, 210, 301, etc.) misses a downlink from primary network node 102. FIGS. 4A and 4B show one example of the response of an example secondary network node 106 to missing a downlink from primary network node 102. In FIGS. 4A and 4B, like components operate similarly to like components described above with respect to FIGS. 3A and 3B. For example, a receive time frame, a DL receive frame, a UL transmit frame, a receive to transmit frame, etc., each operate similarly in FIGS. 4A and 4B as the similarly-named counterparts in FIGS. 3A and 3B.

The primary network node 102 communicates with the first secondary network node 206, the second secondary network node 210, and an Nth secondary network node 301 using, for example, the superframe intervals 400 (shown in FIG. 4A) and 401 (shown in FIG. 4B). As shown, the superframe intervals 400 and 401 include a first DL guard frame 402, a first DL transmit frame 403, a first UL receive frame 404, a second UL receive frame 405, a second DL transmit frame 406, a third UL receive frame 407, a fourth UL receive frame 408, and a fifth UL receive frame 409. The superframe intervals 400 and 401 also include a first DL transmit time frame 410, a first transmit to receive frame 411, a first UL receive time frame 412, a second transmit to receive frame 413, a second UL receive time frame 414, a third transmit to receive frame 415, a third UL receive time frame 416, a second DL guard frame 417, a second DL transmit time frame 418, a fourth transmit to receive frame 419, a fourth UL receive time frame 420, a fifth transmit to receive frame 421, a fifth UL receive time frame 422, a sixth transmit to receive frame 423, and a sixth UL receive time frame 424.

The superframe intervals 400 and 401 also include a first receive wait time 425, a first receive to transmit frame 426, a first UL transmit time frame 427, a second receive wait time 428, a second receive to transmit frame 429, and a second UL transmit time frame 430. The superframe intervals 400 and 401 include a first DL receive frame 431 and a first UL transmit frame 432.

The superframe intervals 400 and 401 also include a third receive wait time 433, a third receive to transmit frame 434, a third UL transmit time frame 435, fourth receive wait time 436, a fourth receive to transmit frame 437, and a fourth UL transmit time frame 438. The superframe intervals 400 and 401 also include a second DL receive frame 439, a second UL transmit frame 440, a third DL receive frame 441, and a third UL transmit frame 442.

The superframe intervals 400 and 401 include a fifth receive wait time 443, a fifth receive to transmit frame 444, a fifth UL transmit time frame 445, a sixth receive wait time 446, a sixth receive to transmit frame 447, and a sixth UL transmit time frame 448. The superframe intervals 400 and 401 also include a fourth DL receive frame 449, a fourth UL transmit frame 450, a fifth DL receive frame 451, and a sixth UL transmit frame 452. The superframe intervals 400 and 401 also include a first frame 453, a second frame 454, a third frame 455, a fourth frame 456, a fifth frame 457, a sixth frame 458, a seventh frame 459, and an eighth frame 460. The frames 453 to 460 may be referred to herein as slots 453 to 460, respectively.

A detailed recitation of the operation of FIGS. 4A and 4B is omitted here for simplicity. However, FIGS. 4A and 4B operate similarly to FIGS. 3A and 3B. In FIGS. 4A and 4B, a primary network node 102 transmits a first DL transmit frame 403 during first frame 453. In this example, first secondary network node 206 misses the DL transmission. An “X” in FIG. 4A during first receive wait time 425 designates the missed DL transmission. The other secondary network nodes 106 in this example (210, 301, etc.) receive the DL transmission. Because first secondary network node 206 missed the DL transmission, first secondary network node 206 does not transmit a UL transmit frame during first UL transmit time frame 427. In this example, rather than listening for UL transmissions from other secondary network nodes 106 during superframe interval 400 (as described above with respect to FIG. 3B), first secondary network node 206 listens for a DL transmission from primary network node 102 during the next superframe interval 401. If a transmission occurs during superframe interval 401, the WBMS 101 is likely operating, and first secondary network node 206 can continue normal operation. As shown in FIG. 4A, first secondary network node 206 does not listen for UL transmission from other secondary network nodes 106 during superframe interval 400. Rather, first secondary network node 206 listens for a transmission during superframe interval 401, and in this example receives the DL transmission at first DL receive frame 431. First secondary network node 206 then responds to primary network node 102 with first UL transmit frame 432. Therefore, the maximum delay in this example scenario is one superframe.

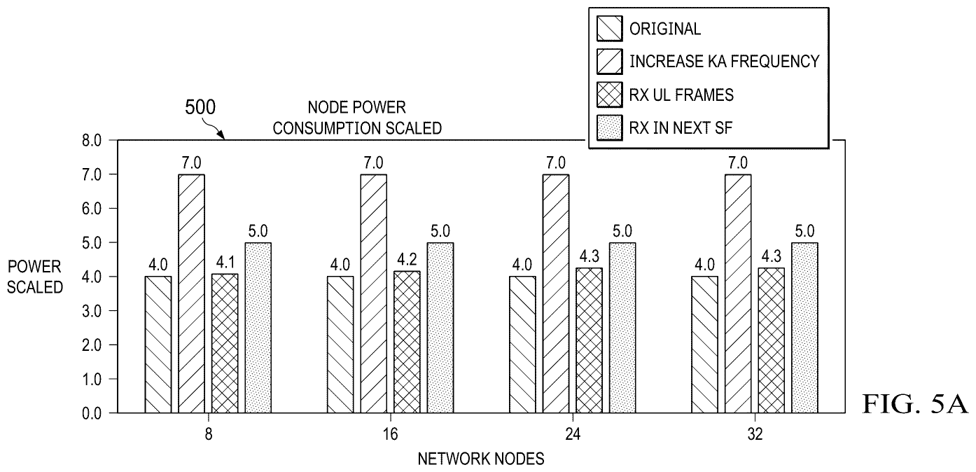

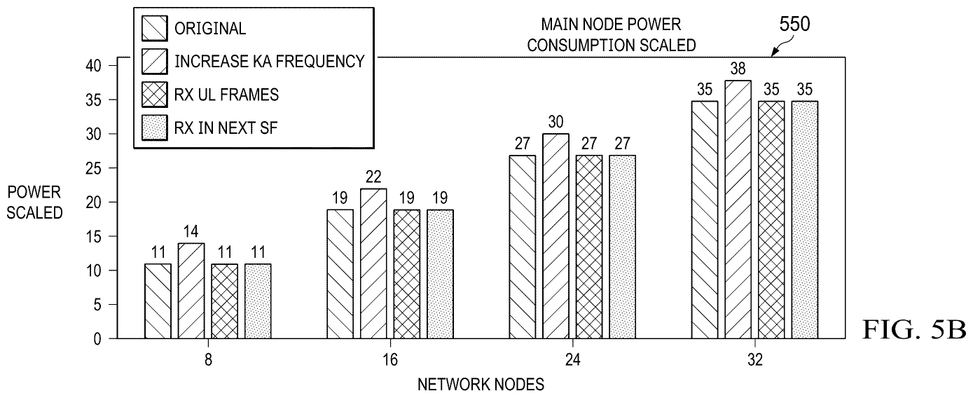

FIGS. 5A and 5B are example graphs of node power consumption in accordance with various examples herein. FIG. 5A is a graph 500 of scaled power consumption for a secondary network node in accordance with various examples herein. The y-axis of graph 500 shows scaled power consumption, while the x-axis shows the number of network nodes for four different scenarios. Examples are shown for 8 nodes, 16 nodes, 24 nodes, and 32 nodes. The four scenarios shown for each node count are an Original scenario, an Increase Keep Alive Frequency scenario, a Receive (RX) in UL Frames scenario, and a RX in Next Superframe scenario. In one example, the primary node may transmit the keep alive frames at less than 300 ms intervals in this scenario. In the Original scenario, a node that misses a DL waits for the next active frame. In the Increase Keep Alive Frequency scenario, the keep alive frequency is increased, so that relatively more superframes have a keep alive signal while relatively fewer superframes remain idle. The RX in UL Frames scenario includes a first secondary network node listening for a UL from other secondary network nodes in a first superframe if the first secondary network node misses a DL in the first superframe. This scenario is described above with respect to FIG. 3B. The RX in Next Superframe scenario includes a first secondary network node listening for a UL from other secondary network nodes in a second superframe if the first secondary network node misses a DL in the first superframe. This scenario is described above with respect to FIGS. 4A and 4B.

In the Original scenario in graph 500, scaled power consumption is approximately 4.0 per node for each node count (8, 16, 24, and 32). In the Increase Keep Alive Frequency scenario, scaled power consumption is approximately 7.0 per node for each node count. In the RX in UL Frames scenario, scaled power consumption per node ranges between about 4.1 and 4.3 for the various node counts. In the RX in Next Superframe scenario, scaled power consumption per node is approximately 5.0 for the various node counts. Therefore, graph 500 shows that the RX in UL Frames scenario or the RX in Next Superframe scenario consume less power at the secondary nodes than the Increase Keep Alive Frequency scenario.

FIG. 5B is a graph 550 of scaled power consumption for a main node (e.g., primary network node 102) in accordance with various examples herein. The y-axis of graph 550 shows scaled power consumption, while the x-axis shows the number of network nodes for four different scenarios. Examples are shown for 8 nodes, 16 nodes, 24 nodes, and 32 nodes. The four scenarios shown for each node count are an Original scenario, an Increase Keep Alive Frequency scenario, a Receive (RX) in UL Frames scenario, and a RX in Next Superframe scenario, which are described above.

In the Original scenario in graph 550, scaled power consumption at the main node is approximately 11 for 8 secondary nodes, 19 for 16 secondary nodes, 27 for 24 secondary nodes, and 35 for 32 secondary nodes. In the Increase Keep Alive Frequency scenario, scaled power consumption at the main node is approximately 14 for 8 secondary nodes, 22 for 16 secondary nodes, 30 for 24 secondary nodes, and 39 for 32 secondary nodes. In the RX in UL Frames scenario, scaled power consumption at the main node is approximately 11 for 8 secondary nodes, 19 for 16 secondary nodes, 27 for 24 secondary nodes, and 35 for 32 secondary nodes. In the RX in Next Superframe scenario, scaled power consumption at the main node is approximately 11 for 8 secondary nodes, 19 for 16 secondary nodes, 27 for 24 secondary nodes, and 35 for 32 secondary nodes. Therefore, graph 500 shows that the RX in UL Frames scenario or the RX in Next Superframe scenario consume less power at the secondary nodes than the Increase Keep Alive Frequency scenario. Therefore, graph 550 shows that the RX in UL Frames scenario or the RX in Next Superframe scenario consume less power at the main node than the Increase Keep Alive Frequency scenario.

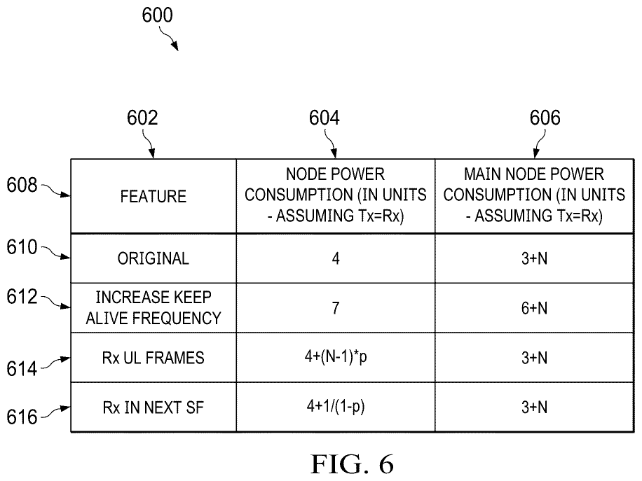

FIG. 6 is a table 600 that shows approximate power consumption at the main node and at secondary network nodes for networks of N nodes in accordance with various examples herein. In this example, the secondary nodes transmit every 3T and receive every T, where T is a time interval. The main node transmits every T and receives every 3T. Column 602 shows the different scenarios. Column 604 shows the approximate power consumption at the secondary nodes, with an assumption that transmit power approximately equals receive power. Column 606 shows the approximate power consumption at the main node, with an assumption that transmit power approximately equals receive power. Row 608 is a header row, and rows 610, 612, 614, and 616 show the four different scenarios described above, respectively (Original, Increase Keep Alive Frequency, RX in UL Frames, and RX in Next Superframe). The numerical values in table 600 are approximate.

In one example, the Original scenario (row 610) has a secondary node power consumption of 4, and the main node power consumption is 3+N. The Increase Keep Alive Frequency scenario (row 612) has a secondary node power consumption of 7, and the main node power consumption is 6+N. Therefore, this scenario consumes more power than the Original scenario, which was also shown in FIGS. 5A and 5B.

Referring again to FIG. 6, the RX in UL Frames scenario has a secondary node power consumption of 4+(N−1)*p, where p is the probability of an error. The RX in UL Frames scenario has a main node power consumption of 3+N. As an example, in a system with 8 secondary nodes and a probability of error of 10%, the secondary node power consumption in this scenario would be 4+(8−1)(0.10), or approximately 4.7. If the probability of error were 0.1%, the secondary node power consumption would be 4+(8−1)(0.001), or approximately 4.007. Therefore, the power consumption goes down as the probability of error decreases. Also, in this scenario, the secondary node power consumption goes up as N increases.

The RX in Next Superframe scenario has a secondary node power consumption of 4+1/(1−p), where p is the probability of an error. The RX in Next Superframe scenario has a main node power consumption of 3+N. As an example, in a system with 8 secondary nodes and a probability of error of 10%, the secondary node power consumption in this scenario would be 4+1/(0.9), or approximately 5.1. If the probability of error were 0.1%, the secondary node power consumption would be 4+1/(0.999), or approximately 5.001. Therefore, the power consumption goes down as the probability of error decreases in this scenario as well.

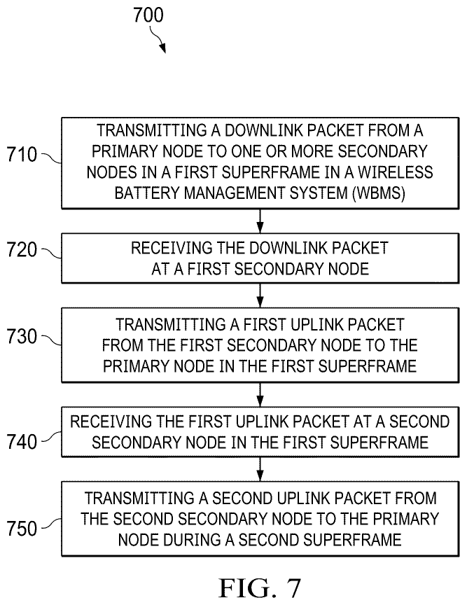

FIG. 7 is a flow diagram of a method for a network restart from a power save mode in accordance with various examples herein. The steps of method 700 may be performed in any suitable order. The hardware components described above with respect to FIGS. 1-2 may perform method 700 in some examples.

Method 700 begins at 710, where primary network node 102 transmits a downlink packet to one or more secondary nodes in a first superframe in a WBMS. The first superframe may be superframe 300 in one example, and the secondary nodes may be secondary nodes 206, 210, and/or 301.

Method 700 continues at 720, where a first secondary node receives the downlink packet. In one example, secondary node 206 fails to receive the downlink packet and secondary node 210 receives the downlink packet. Therefore, secondary node 210 is the first secondary node in this example. Responsive to failing to receive an expected downlink packet, secondary node 206 may turn on its receiver to listen for uplink packets from other secondary nodes (210, 301, etc.).

Method 700 continues at 730, where the first secondary node (e.g., node 210) transmits a first uplink packet from the first secondary node to the primary network node 102 in the first superframe (e.g., superframe 300). In one example, the first uplink packet is transmitted using the second UL transmit frame 338.

Method 700 continues at 740, where a second secondary node (e.g., node 206) receives the first uplink packet in the first superframe. In an example, the first uplink packet is received at the fourth UL receive frame 372. As described above, second secondary node 206 listens for uplink packets from other secondary nodes such as node 210. If second secondary node 206 receives an uplink packet, second secondary node 206 knows the WBMS 101 is active and can then prepare for operation.

Method 700 continues at 750, where the second secondary node transmits a second uplink packet to the primary network node 102 during a second superframe. The second secondary node (e.g., node 206) waits until the next superframe after the first superframe so the second secondary node 206 can transmit the second uplink packet during an appropriate slot.

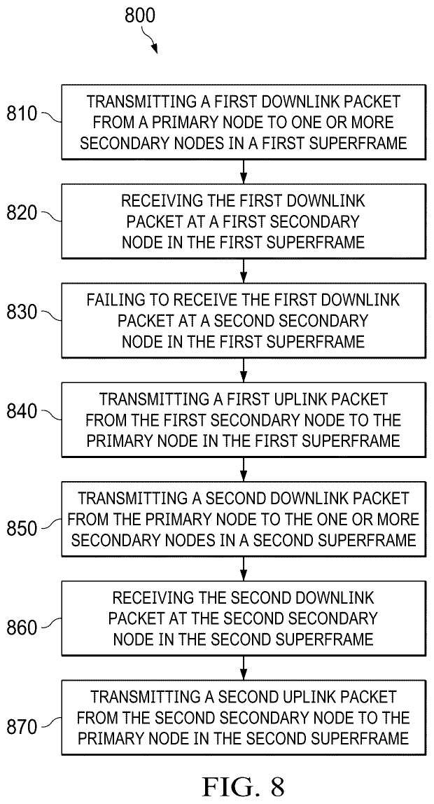

FIG. 8 is a flow diagram of a method for a network restart from a power save mode in accordance with various examples herein. The steps of method 800 may be performed in any suitable order. The hardware components described above with respect to FIGS. 1-2 may perform method 800 in some examples. Method 800 may be performed when a WBMS is exiting a low-power state, such as a sleep or idle state, and re-activating all of the nodes in the WBMS.

Method 800 begins at 810, where a primary network node 102 transmits a first downlink packet to one or more secondary nodes in a first superframe in a WBMS. The first superframe may be superframe 400 in one example, and the secondary nodes may be secondary nodes 206, 210, and/or 301. The first downlink packet may be transmitted in a first slot of the superframe 400.

Method 800 continues at 820, where a first secondary node receives the first downlink packet in the first superframe (e.g., superframe 400). The first downlink packet may be received in the first slot of the superframe 400. In one example, secondary node 206 fails to receive the downlink packet and secondary node 210 receives the downlink packet. Therefore, secondary node 210 is the first secondary node in this example. Responsive to failing to receive an expected downlink packet, secondary node 206 may be configured to turn on its receiver to listen for uplink packets from other secondary nodes (210, 301, etc.).

Method 800 continues at 830, where the second secondary node (e.g., node 206) fails to receive the first downlink packet in the first superframe. In one example, the “X” in FIG. 4A during first receive wait time 425 designates the missed DL transmission at node 206. Secondary node 206 may miss the first downlink packet because of interference or because secondary node 206 is not listening for the first downlink packet when the primary node sends the first downlink packet.

Method 800 continues at 840, where the first secondary node (e.g., node 210) transmits a first uplink packet to the primary network node 102 in the first superframe 400. As one example, the first uplink packet is transmitted using the second UL transmit frame 440. Node 210 sends the first uplink packet in response to receiving the first downlink packet. Each of the secondary nodes may be capable of determining its respective slot within superframe 400, as explained in commonly assigned U.S. patent application Ser. No. 17/828,895, entitled “Efficient Unicast Super Frame Communications,” filed on May 31, 2022, which is incorporated by reference in its entirety.

Method 800 continues at 850, where the primary network node 102 transmits a second downlink packet to the one or more secondary nodes in a second superframe. The second superframe may be superframe 401 in one example, and the first and second superframes may be consecutive superframes. The second downlink packet may be transmitted using the second DL transmit frame 406 in one example. The second downlink packet may be transmitted in a second slot in the superframe 401.

Method 800 continues at 860, where the second secondary node (e.g., node 206) receives the second downlink packet in the second superframe 401. As an example, the second downlink packet is received at first DL receive frame 431. The second downlink packet may be received in the second slot of the second superframe 401.

Method 800 continues at 870, where the second secondary node (e.g., node 206) transmits a second uplink packet to the primary network node 102 in the second superframe 401. As an example, the second uplink packet is transmitted at first UL transmit frame 432. The second uplink packet may be transmitted in a third slot of the second superframe 401.

In examples herein, a first secondary node that fails to receive an expected downlink packet from the primary node during an active superframe may turn on its receiver to opportunistically listen to other frames being transmitted from other secondary nodes to the primary node during the active superframe. If the first secondary node receives a transmission from another secondary node, the first secondary node wakes up and enters an active state. In other examples herein, the first secondary node that misses the downlink packet from the primary node can listen with its receiver during the next superframe, rather than the current superframe. If there is any activity in the next superframe, then the WBMS is active, and the first secondary node can continue normal operation. In examples herein, the nodes may consume minimal power during an off state (e.g., a keep alive power save state), while still being able to start up quickly and have the WBMS operating in under 300 ms.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Unless otherwise stated, “about,” “approximately,” or “substantially” preceding a value means+/−10 percent of the stated value. Modifications are possible in the described examples, and other examples are possible within the scope of the claims.

What is claimed is:

1. A wireless battery management system (WBMS), comprising:
one or more sets of battery cells;
a primary node configured to broadcast a downlink packet in a first superframe;
a first secondary node coupled to a first set of battery cells, the first secondary node configured to:
receive the downlink packet; and
transmit a first uplink packet to the primary node during the first superframe; and
a second secondary node coupled to a second set of battery cells, the second secondary node configured to:
receive the first uplink packet from the first secondary node in the first superframe; and
transmit a second uplink packet to the primary node during a second superframe.

2. The WBMS of claim 1, wherein the first superframe and the second superframe are consecutive superframes.

3. The WBMS of claim 1, wherein the second secondary node fails to receive the downlink packet.

4. The WBMS of claim 3, wherein the second secondary node includes a receiver, and wherein, responsive to failing to receive the downlink packet, the second secondary node turns on the receiver.

5. The WBMS of claim 1, wherein the first secondary node receives the downlink packet in a first slot of the first superframe and transmits the first uplink packet in a second slot of the first superframe.

6. The WBMS of claim 5, wherein the second secondary node receives the first uplink packet in the second slot.

7. A method, comprising:
transmitting a downlink packet from a primary node to one or more secondary nodes in a first superframe in a wireless battery management system (WBMS);
receiving the downlink packet at a first secondary node;
transmitting a first uplink packet from the first secondary node to the primary node in the first superframe;
receiving the first uplink packet at a second secondary node in the first superframe; and
transmitting a second uplink packet from the second secondary node to the primary node during a second superframe.

8. The method of claim 7, wherein the first secondary node is coupled to a first set of battery cells, and the second secondary node is coupled to a second set of battery cells.

9. The method of claim 7, wherein the primary node transmits the downlink packet in a first slot of the first superframe, and the first secondary node receives the downlink packet in the first slot.

10. The method of claim 9, wherein the first secondary node transmits the first uplink packet in a second slot of the first superframe.

11. The method of claim 10, wherein the second secondary node fails to receive the downlink packet.

12. The method of claim 11, wherein the second secondary node includes a receiver, and wherein, responsive to failing to receive the downlink packet, the second secondary node turns on the receiver.

13. The method of claim 12, wherein the second secondary node receives the first uplink packet in the second slot.

14. The method of claim 7, wherein the first superframe and the second superframe are consecutive superframes.

15. A method, comprising:
transmitting a first downlink packet from a primary node to one or more secondary nodes in a first superframe;
receiving the first downlink packet at a first secondary node in the first superframe;
failing to receive the first downlink packet at a second secondary node in the first superframe;
transmitting a first uplink packet from the first secondary node to the primary node in the first superframe;
transmitting a second downlink packet from the primary node to the one or more secondary nodes in a second superframe;
receiving the second downlink packet at the second secondary node in the second superframe; and
transmitting a second uplink packet from the second secondary node to the primary node in the second superframe.

16. The method of claim 15, wherein the first superframe and the second superframe are consecutive superframes.

17. The method of claim 15, wherein the first secondary node is coupled to a first set of battery cells, and the second secondary node is coupled to a second set of battery cells.

18. The method of claim 15, wherein the primary node transmits the first downlink packet in a first slot of the first superframe, and the first secondary node receives the first downlink packet in the first slot.

19. The method of claim 18, wherein the primary node transmits the second downlink packet in a second slot of the second superframe, and the second secondary node receives the second downlink packet in the second slot of the second superframe.

20. The method of claim 19, wherein the second secondary node transmits the second uplink packet in a third slot of the second superframe.
